(19) United States
(12) Patent Application Publication
(10) Pub. No.: US 2008/0123021 A1
(43) Pub. Date: May 29, 2008

(54) LIGHT EMITTING DIODE PACKAGE, BACKLIGHT UNIT AND LIQUID CRYSTAL DISPLAY HAVING THE SAME

(76) Inventors: Se Ki Park, Suwon-Si (KR); Gi Cherl Kim, Yongin-Si (KR)

Correspondence Address: Frank Chau, Esq.;F. CHAU & ASSOCIATES, LLC, 130 Woodbury Road, Woodbury, NY, 11797, US

(21) Appl. No.: 11/946,528

(22) Filed: Nov. 28, 2007

(30) Foreign Application Priority Data
Nov. 28, 2006 (KR) 10-2006-0118008

(51) Int. Cl. G02F 1/1335; H01L 33/00; F21V 7/00

(52) U.S. Cl. 349/67; 257/89; 362/231; 257/E33.067

(57) ABSTRACT

A LED package includes a substrate in which a reflective part is formed in a recessed shape, and at least one LED chip that is mounted on the reflective part of the substrate. In this case, the reflective part includes a base surface and a sidewall that is inclined at a first angle with respect to the base surface, and the LED chip is mounted on the sidewall. Further, a backlight unit and a liquid crystal display include the LED package.

### CROSS-REFERENCE TO RELATED APPLICATION

This application claims priority to Korean Patent Application No. 2006-0118008 filed on Nov. 28, 2006, the disclosure of which is hereby incorporated by reference herein in its entirety.

### BACKGROUND OF THE INVENTION

1. Technical Field

The present disclosure relates to a light emitting diode (LED) package, a backlight unit and a liquid crystal displaying unit having the same, and particularly, to a LED package with improved coloring mixing, a backlight unit and a liquid crystal displaying unit including the LED package.

2. Discussion of the Related Art

For example, light bulbs, light emitting diodes (LED), fluorescent lights and metal halide lamps are generally used as light sources for backlight units of liquid crystal displaying units. Recently, backlight units using light emitting diodes, which can achieve lower electricity consumption, lighter weight and more compactness than the back light units using cold cathode fluorescent light (CCFL) in the related art, are being developed. A backlight unit may use, for example, a light source unit which includes a light emitting diode array in which a plurality of light emitting diodes are arranged on a printed circuit board in a row or in a matrix.

It is possible to use both a multi-chip LED package which has a plurality of LED chips in a single package and a single-chip LED package which has one LED chip in a single package.

A multi-chip LED package packs a LED chip with two or more colors in a single package, and a molding part is formed on top of it. The multi-chip LED package, compared to the single-chip LED package, is beneficial for color mixing. More particularly, the multi-chip LED package is relatively improved with regard to color mixing than the single-chip LED package in color mixing, but, when compared to other types of light sources used as backlights, the color mixing properties of the multi-chip LED package may be insufficient.

### SUMMARY OF THE INVENTION

In accordance with an exemplary embodiment of the present invention, a LED package is provided. The LED package includes a substrate in which an inner wall is formed in a recessed shape, and at least one LED chip mounted on the inner wall of the substrate. The inner wall includes a base surface and a sidewall inclined at a first angle with respect to the base surface, and the LED chip is mounted on the sidewall.

The base surface and the sidewall may be integrally formed.

A plurality of the LED chips may be mounted on the sidewall at an interval.

The plurality of LED chips may be mounted on the sidewall at a equal interval.

The first angle may be in the range of from about 120 to about 150°.

The inner wall may include a reflective part.

The LED package may further include a protrusion formed on the base surface.

The protrusion may be formed to have a height equal to or smaller than a depth of the reflective part.

The protrusion may include a reflective surface that is inclined at a second angle with respect to the base surface.

The second angle may be in the range of from about 5 to about 85°.

The protrusion may be formed in a conical shape or a polypyramidal shape.

The LED chip may include at least one of a red LED chip, a green LED chip, and a blue LED chip.

The LED chip may include a white LED chip.

The LED package may further include lead terminals and wires used to apply power to the LED chip.

The LED package may further include a molding part for sealing the LED chip.

The base surface may be formed in a circular shape, a polygonal shape, or a polygonal shape having curves.

The sidewall may include a flat surface.

In accordance with an exemplary embodiment of the present invention, a backlight unit is provided. The backlight unit includes a LED package and a light source unit including a printed circuit board on which the LED package is mounted. The LED package includes a substrate in which a reflective part is formed in a recessed shape, and a plurality of LED chips mounted on the reflective part of the substrate. The reflective part includes a base surface and a sidewall that is inclined at a first angle with respect to the base surface. Moreover, the plurality of LED chips are mounted on the sidewall.

The backlight unit may further include a protrusion that includes a reflective surface inclined at a second angle with respect to the base surface.

In accordance with an exemplary embodiment of the present invention, a backlight unit is provided. The backlight unit includes a LED package, and a light source unit including a printed circuit board on which a plurality of the LED packages is mounted. The LED package includes a substrate in which a reflective part is formed in a recessed shape, and a single LED chip mounted on the reflective part of the substrate. The reflective part includes a base surface and a sidewall inclined at a first angle with respect to the base surface. Also, the single LED chip is mounted on the sidewall. In this case, the plurality of LED packages is divided into LED package units, wherein each LED package unit includes a plurality of LED packages, so as to be mounted on the printed circuit board.

The backlight unit may further include a protrusion that includes a reflective surface inclined at a second angle with respect to the base surface.

According to exemplary embodiment of the present invention, a liquid crystal display may include the above-mentioned backlight unit and a liquid crystal display panel disposed on the backlight unit to display an image.

### BRIEF DESCRIPTION OF THE DRAWINGS

Exemplary embodiments of the present invention can be understood in more detail from the following descriptions taken in conjunction with the accompanying drawings, in which:

FIG. 1 is a perspective view of a LED package according to an exemplary embodiment of the present invention;

FIGS. 2A and 2B are a layout view of LED chips of the LED package shown in FIG. 1 and a cross-sectional view of the LED package, respectively;

FIGS. 3A and 3B are views of modifications of the LED package shown in FIG. 1;

FIGS. 4A and 4B are a perspective view and a cross-sectional view of a LED package in the related art, respectively;

FIGS. 5A and 5B are diagrams showing results of light distribution and chroma data of LED packages according to the related art and an exemplary embodiment of the present invention;

FIG. 6 is a table comparing the level of color mixing of the LED package between the related art and an exemplary embodiment of the present invention;

FIGS. 7 and 8 are a perspective view and a cross-sectional view of a LED package according to an exemplary embodiment of the present invention, respectively;

FIG. 9 is a schematic draft of the LED package shown in FIGS. 7 and 8;

FIGS. 10A to 10E are views of modifications of the LED package shown in FIGS. 7 and 8;

FIG. 11 is a table comparing the level of color mixing of the LED package between the related art and the modifications of FIGS. 10A to 10E;

FIGS. 12A to 12E are views of modifications of the LED package shown in FIGS. 7 and 8;

FIG. 13 is a table comparing the level of color mixing of the LED package between the related art and the modifications of FIGS. 12A to 12E;

FIGS. 14A and 14B are a plan view and a perspective view of a LED package according to an exemplary embodiment of the present invention, respectively; and

FIGS. 15 and 16 are exploded perspective views of one and another examples of a liquid crystal display that is provided with a backlight including the LED packages according an exemplary embodiment of the present invention.

### DESCRIPTION OF THE EXEMPLARY EMBODIMENTS

Exemplary embodiments of the invention are described more fully hereinafter with reference to the accompanying drawings. This invention may, however, be embodied in many different forms and should not be construed as limited to the exemplary embodiments set forth herein.

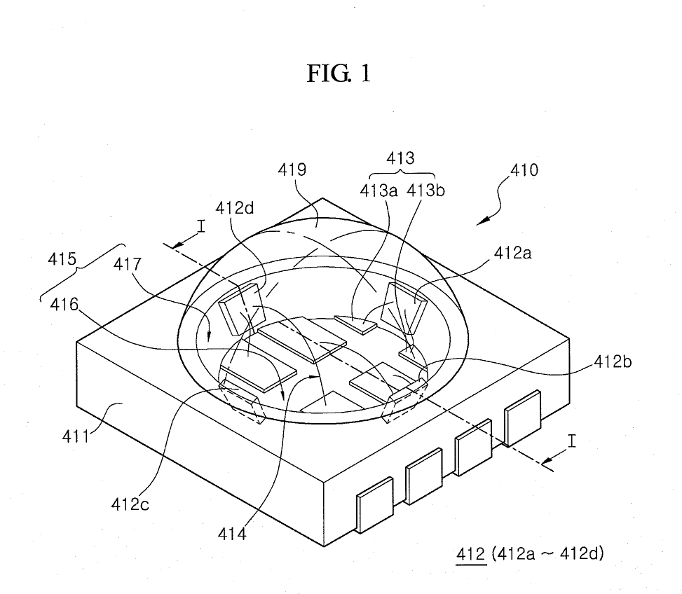

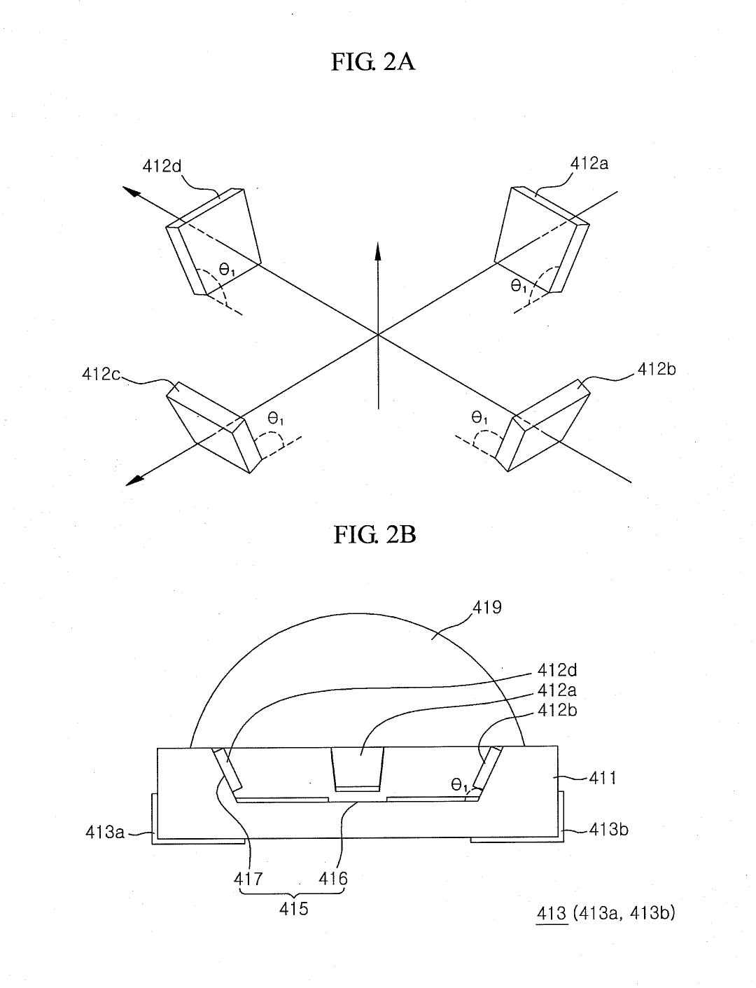

FIG. 1 is a perspective view of a LED package according to an exemplary embodiment of the present invention, and FIGS. 2A and 2B are a layout view of LED chips of the LED package shown in FIG. 1 and a cross-sectional view of the LED package.

Referring to FIGS. 1 to 2B, a LED package 410 according to an exemplary embodiment of the present invention includes a substrate 411, LED chips 412, a lead terminal 413, wires 414, an inner wall 415, and a molding part 419.

The inner wall 415 having, for example, a recessed shape is formed on one surface of the substrate 411, that is, an upper surface of the substrate. The inner wall 415 includes a base surface 416 that is parallel to the one surface of the substrate 411 and is formed to have a predetermined recessed depth, and a sidewall 417 that is inclined at a first angle θ₁ with respect to the base surface 416. In this case, the base surface 416 is formed in, for example, a circular shape, and the base surface 416 and sidewall 417 may be integrally formed.

The LED chips 412 are mounted on the sidewall 417 of the inner wall 415 so as to be inclined at the first angle θ₁ with respect to the base surface 416. At this time, the LED chips 412 are composed of first to fourth LED chips 412a to 412d, and the LED chips 412a to 412d are mounted at predetermined intervals on the sidewall. According to this embodiment, the LED chips 412a to 412d are mounted at a regular interval, but the present invention is not limited thereto. In addition, the first LED chip 412a is a blue LED chip which emits blue light, the second LED chip 412b is a green LED chip which emits green light, the third LED chip 412c is a red LED chip which emits red light, and the fourth LED chip 412d is a green LED chip which emits green light. Alternatively, the first to fourth LED chips 412a to 412d may be white LED chips which emit white light. In other words, the LED chips 412 may emit light with various wavelengths. For this purpose, for example, the amount of indium (In) that is used as an active layer in a nitride-based LED package may be controlled, LED packages for emitting light with different wavelengths may be combined, or a LED chip for emitting light in a predetermined wavelength band such as ultraviolet rays may be combined with a fluorescent substance. The number and type of the LED chips used in this embodiment and the mounting intervals between the LED chips are illustrative and may be modified in various ways.

The angle between the LED chips 412 and the base surface 416, that is, the first angle θ₁ may be changed in the range of about 120 to about 150°. In this embodiment, the first angle θ₁ is about 135°.

The lead terminal 413, which is composed of a first lead terminal 413a and a second lead terminal 413b, is disposed to the substrate 411. One end of the lead terminal 413 is disposed on the base surface 416 and exposed to the outside, and the other end thereof is bent along the sidewall of the substrate and disposed on the other surface of the substrate 411, that is, the lower surface. Alternatively, the other end of the lead terminal 413 may extend to the outside of the substrate 411.

The wires 414 are connected to the LED chips 412, the first lead terminal 413a, and the second lead terminal 413b. When being applied to the first lead terminal 413a and the second lead terminal 413b, external power is supplied to a P electrode and an N electrode of each LED chip 412 through the wires 414, so that each of the LED chips 412 emits light of a predetermined wavelength.

The molding part 419, which seals the LED chips 412 and the wire 414, is formed on the substrate 411. In this case, the molding part 419 may be formed in various shapes, such as, for example, an optical lens shape and a flat shape. In the present embodiment, the molding part is formed in, for example, a semicircular shape or a dome shape. The molding part 419 may be made of transparent resin, such as, for example, liquid epoxy resin or silicon resin. The molding part 419 may have a fluorescent substance mixed therein to absorb light emitted from the LED chips 412 and convert the light into light having various wavelengths.

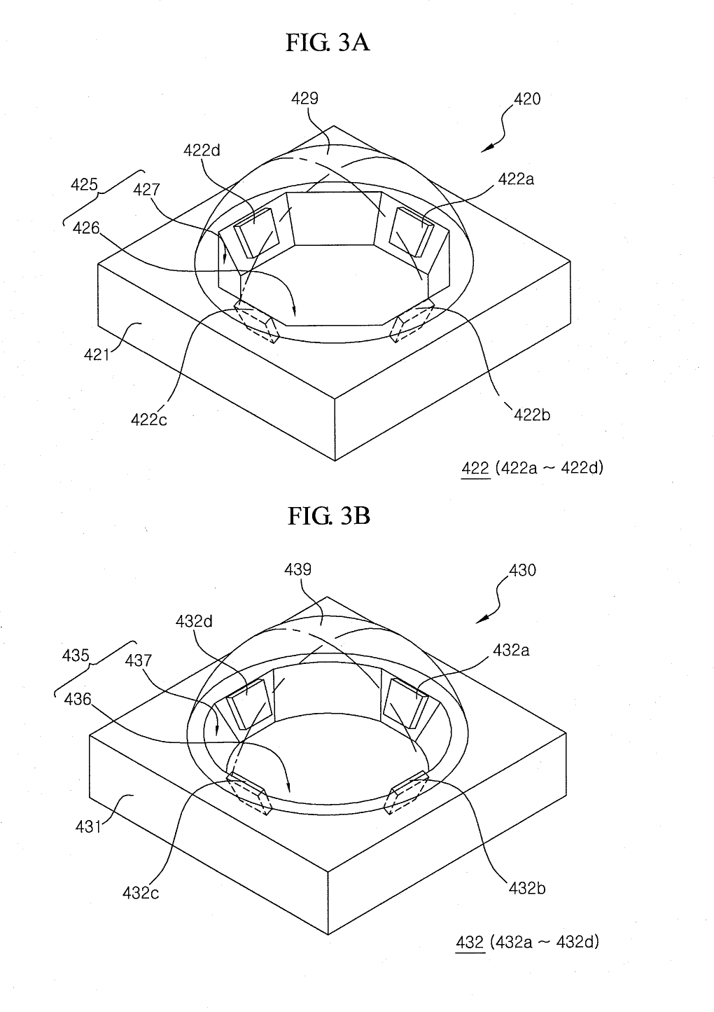

FIGS. 3A and 3B are views of modifications of the LED package shown in FIG. 1. The same components as those shown in FIG. 1 will not be described, and different constitution from that of FIG. 1 will be mainly described in detail.

Referring to FIG. 3A, a LED package 420 includes a substrate 421, LED chips 422, lead terminals, wires, a inner wall 425, and a molding part 429.

The inner wall 425 having a recessed shape is formed on the upper surface of the substrate 421. The reflective part 425 includes a base surface 426 that is parallel to the upper surface of the substrate 421 and is formed to have a predetermined recessed depth, and a sidewall 427 that is inclined at a predetermined angle with respect to the base surface 426. In this case, the base surface 426 is formed in a polygonal shape, for example, an octagonal shape. The sidewall 427 extending from the base surface 426 is composed of eight sidewalls, and each of the sidewalls is formed of a flat surface, not a curved surface, which makes it easier to mount the LED chip 422 on the sidewall.

In the meantime, referring to FIG. 3B, a LED package 430 includes a substrate 431, LED chips 432, lead terminals, wires a inner wall 435, and a molding part 439.

A base surface 436 of the inner wall 435 may be formed, for example, in a polygonal shape partially including curves. As the base surface 436 is formed in a polygonal shape partially including curves, a sidewall 437 is also composed of flat and curved sidewalls. In this case, the LED chips 432 are mounted on the flat sidewalls.

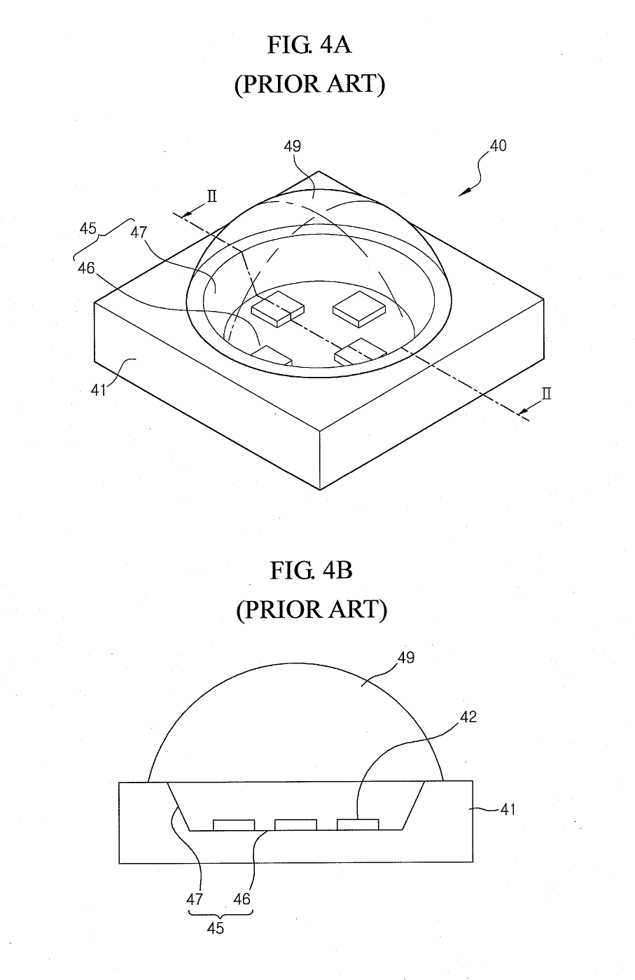

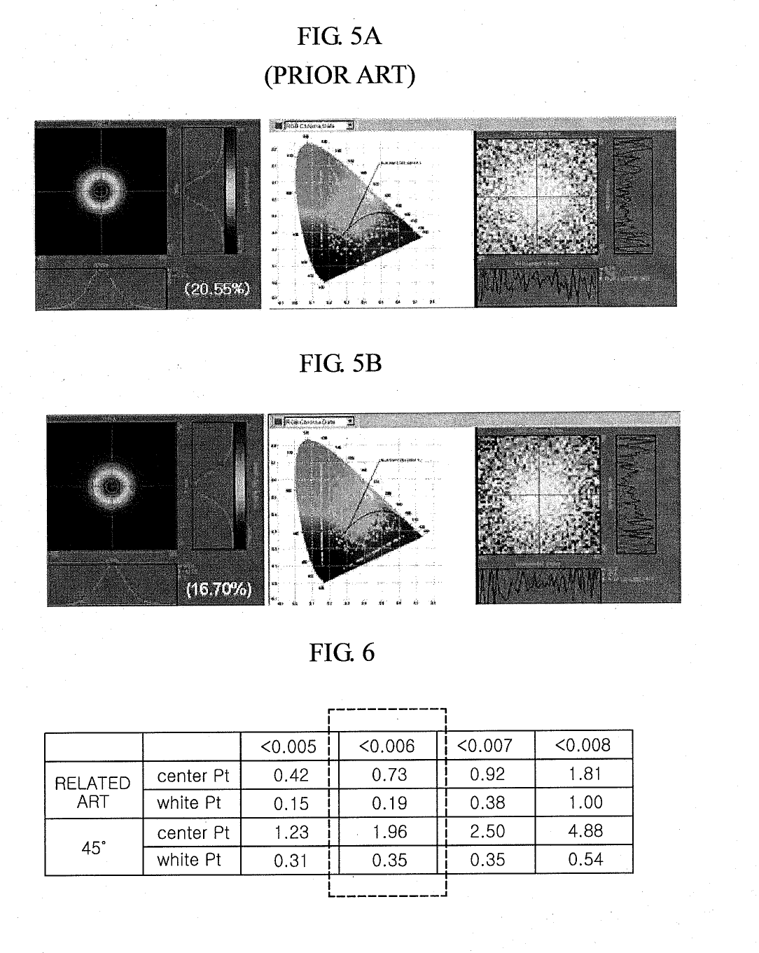

FIGS. 4A and 4B are a perspective view and a cross-sectional view of a LED package in the related art. FIGS. 5A and 5B are diagrams showing results of light distribution and chroma data of LED packages according to the related art and an embodiment of the present invention. FIG. 6 is a table comparing the level of color mixing of the LED package between the related art and an embodiment of the present invention.

A LED package 40 according to the related art illustrated in FIGS. 4A and 4B includes a substrate 41, LED chips 42, lead terminals, wires, a reflective part 45 having a recessed shape, and a molding part 419. The LED chips 42 are mounted on the bottom surface of the reflective part 45.

FIGS. 5A to 6 illustrate simulation results of LED packages according to the related art and embodiments of the present invention. According to specifications of the simulated LED packages according to the related art and present invention, the total size is, for example, about 3×3×0.7 millimeter (mm), R, G, and B LED chips of about 350×350 μm are used as the LED chips, and the molding part is formed to have a height of about 0.3 mm. Simulations are performed under conditions in which the LED package according to the related art has the LED chips mounted on the bottom surface of the reflective part, and the LED package according to the present invention has the LED chips mounted to be inclined at about 135° with respect to the bottom surface of the reflective part.

The positions of white points and the level of Δu′v′ can be obtained from chroma data. Here, each of the data indicates how many points (percentage %) are found below about 0.006, in the value of color difference obtained with respect to a center Pt of a detector or a white Pt (that is, u′v′=about 0.198, about 0.468).

In the related art, Δu′v′, that is, the number of points below about 0.006 in the value of color difference is about 0.19 out of 100. The reason why the number is so small is that a perfect white point value is set as reference and light emitted from one LED package is detected by a detector with the size of about 100×100 mm. If simulation is performed under different conditions, for example, if light emitted from the LED package is measured after a detector is positioned directly on the LED package, or if the detector is increased in size, the large value can be measured.

As shown in FIG. 6, according to the case in which the value of color difference is below about 0.006 in respect to the white point, Δu′v′ with respect to the white Pt is about 0.35 in the present invention (when the first angle is about 135°), which is improved by about 84% as compared to the related art in which Δu′v′ with respect to the white Pt is about 0.19. Therefore, color mixing, that is, white color mixing is improved when the LED chip is mounted on the sidewall of the reflective part, as compared to when the LED chip is mounted on the bottom surface of the reflective part.

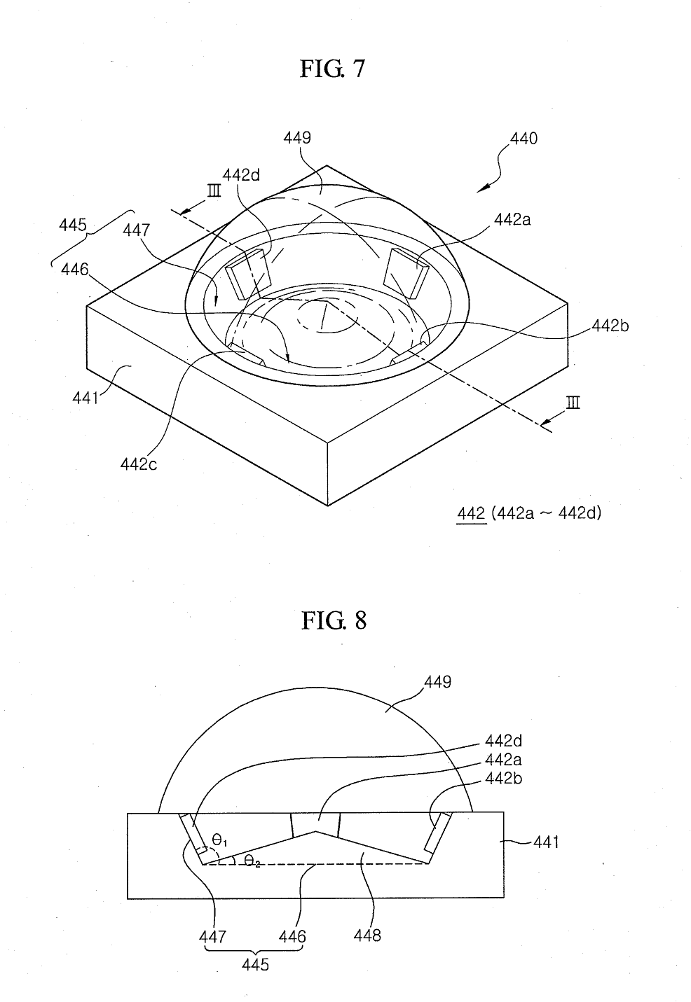

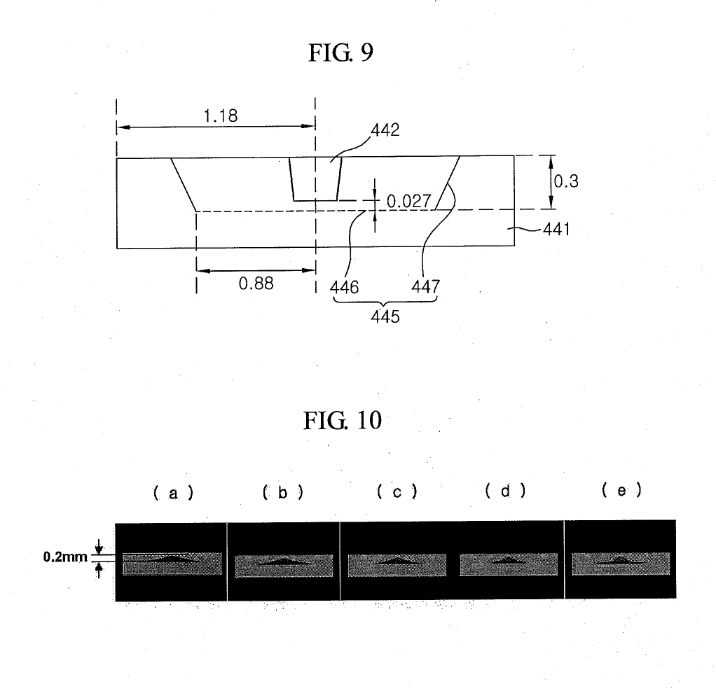

FIGS. 7 and 8 are a perspective view and a cross-sectional view of a LED package according to another embodiment of the present invention, and FIG. 9 is a schematic draft of the LED package shown in FIGS. 7 and 8.

Referring to FIGS. 7 to 9, a LED package 440 according to another embodiment of the present invention includes a substrate 441, LED chips 442, lead terminals, wires, an inner wall 445, a protrusion 448, and a molding part 449.

The inner wall 445 comprises a reflective part, and the reflective part 445 having a recessed shape is formed on one surface of the substrate 441, that is, an upper surface of the substrate. The reflective part 445 includes a base surface 446 that is parallel to the one surface of the substrate 441 and formed to have a predetermined recessed depth, and a sidewall 447 that is inclined at a first angle θ₁ with respect to the base surface 446. In this case, the base surface 446 is formed in, for example, a circular shape, but is not limited to the circular shape. As described above, the base surface may be formed in various shapes, such as, for example, a polygonal shape or a polygonal shape having curves.

The LED chips 442 are mounted on the sidewall 447 of the reflective part 445 so as to be inclined at the first angle θ₁ with respect to the base surface 446. At this time, the LED chips 442 are composed of first to fourth LED chips 442a to 442d, and the LED chips 442a to 442d are mounted at predetermined intervals on the sidewall. In the present embodiment, the LED chips 442a to 442d are mounted at a regular interval, but the present invention is not limited thereto.

The protrusion 448 is formed in the reflective part 445, the protrusion 448 is formed on the base surface 446 of the reflective part 445, and the protrusion 448 includes a reflective surface that is inclined at a second angle θ₂ with respect to the base surface 446. The protrusion 448 is formed in, for example, a conical shape as a whole, but is not limited thereto. The protrusion may be modified in various shapes, such as, for example, a polypyramidal shape.

In addition, the protrusion 448 is formed to have height equal to or smaller than the depth of the reflective part 445. Further, the second angle θ₂ between the reflective surface of the protrusion 448 and the base surface 446 may be changed within the range of about 5 to about 85°. As described above, if the protrusion 448 is formed on the base surface 446 of the reflective part 445, it is possible to further improve the color mixing effect.

FIG. 9 shows an exemplary draft of the LED package 440. The reflective part 445 of the LED package 440 has a depth of about 0.3 mm, a distance between the center of the base surface 446 and one end of the sidewall 447 is about 0.88 mm, and a distance between the center of the base surface 446 to the other end of the sidewall 447 is about 1.18 mm. The LED chip 442 is mounted on the sidewall 447 so as to be spaced apart from the base surface 446 by a distance of about 0.027 mm. The LED package 440 shown in FIG. 9 is illustrative, and the type and dimension of the LED package are not limited thereto.

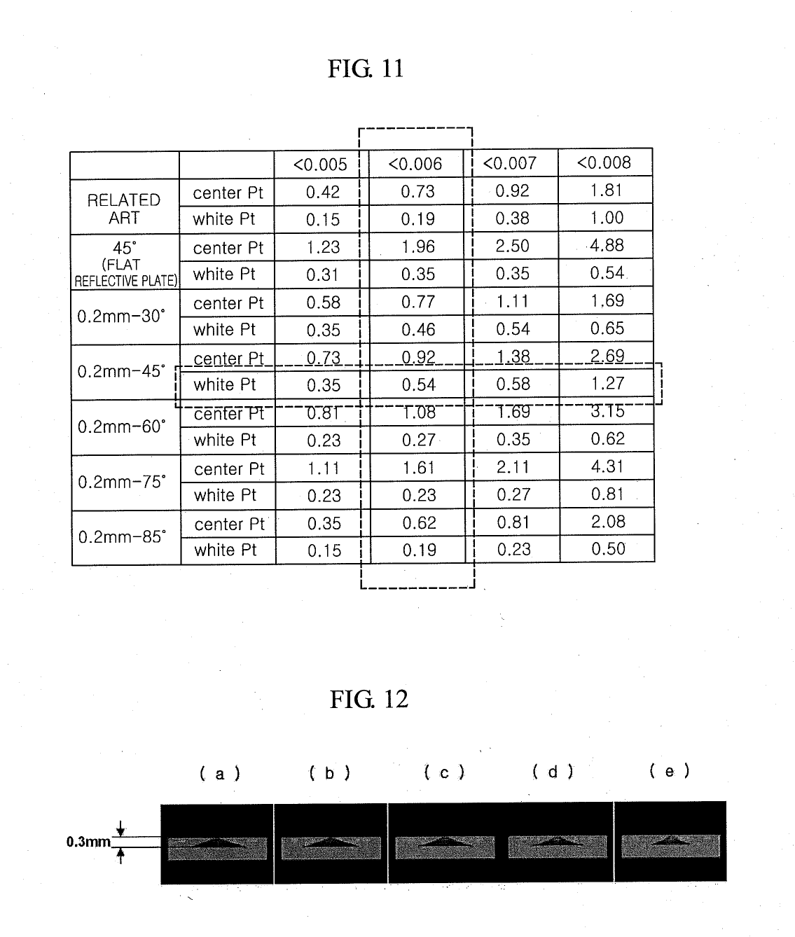

FIGS. 10A to 10E are modifications of the LED package shown in FIGS. 7 and 8. FIG. 11 is a table comparing the level of color mixing of the LED package between the related art and the modifications of FIGS. 10A to 10E.

FIGS. 10A to 10E are schematic cross-sectional views of the LED package when an angle between the reflective surface of the protrusion and the base surface, that is, the second angle θ₂ is modified to about 30, about 45, about 60, about 75, and about 85°. At this time, the protrusion of the LED package is formed to have a height of about 0.2 mm, and the reflective part is formed to have a depth of about 0.3 mm.

FIG. 11 is a table comparing the level of color mixing of the LED package between the related art, the first embodiment (the LED package without the protrusion shown in FIG. 1) of the present invention and the modifications (the LED package shown in FIGS. 10A to 10E) of the present invention.

According to the case in which the value of color difference is below about 0.006 with respect to the white point, Δu′v′ with respect to the white Pt is about 0.19 in the LED package according to the related art, Δu′v′ with respect to the white Pt is about 0.35 in the LED package shown in FIG. 1, and Δu′v′ with respect to the white Pt are about 0.46 (θ₂=about 30), about 0.54 (θ₂=about 45), about 0.27 (θ₂=about 60), about 0.23 (θ₂=about 70), and about 0.19 (θ₂=about 85), respectively, in the LED packages shown in FIGS. 10A to 10E.

On the table, the optimal result is about 0.54 obtained when the second angle θ₂ is about 45°, which is improved by about 184% in color mixing as compared to the related art (0.19). FIGS. 12A to 12E are views of other modifications of the LED package shown in FIGS. 7 and 8, and FIG. 13 is a table comparing the level of color mixing of the LED package between the related art and the modifications of FIGS. 12A to 12E.

FIGS. 12A to 12E are schematic cross-sectional views of the LED package, when the angle between the reflective surface of the protrusion and the base surface, that is, the second angle θ₂ is modified to about 30, about 45, about 60, about 75, and about 85°. At this time, the protrusion of the LED package is formed to have a height of about 0.3 mm, and the reflective part is formed to have a depth of about 0.3 mm.

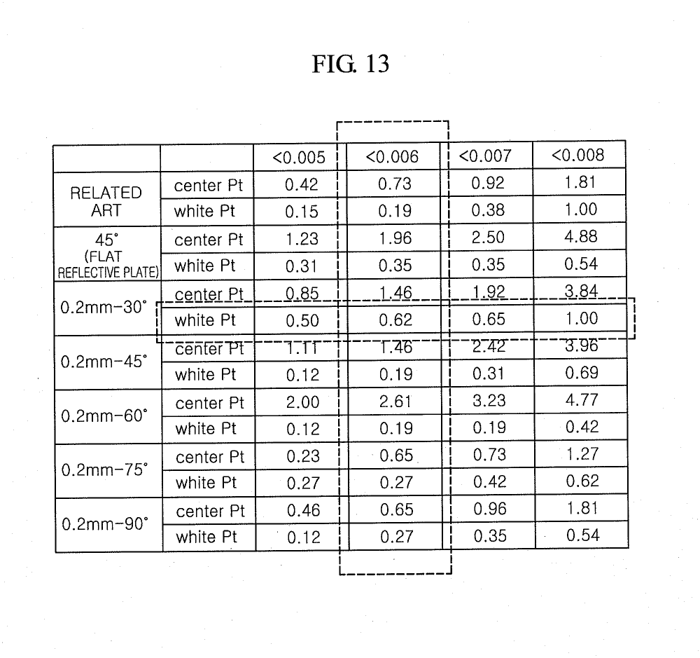

FIG. 13 is a table comparing the level of color mixing of the LED package between the related art, the first embodiment (the LED package without the protrusion shown in FIG. 1) of the present invention and the modifications (the LED packages shown in FIGS. 12A to 12E).

According to the case in which the value of color difference is below about 0.006 in respect to the white point, Δu′v′ with respect to the white Pt is about 0.19 in the LED package according to the related art, Δu′v′ with respect to the white Pt is about 0.35 in the LED package shown in FIG. 1, and Δu′v′ with respect to the white Pt are about 0.62 (θ₂=about 30), about 0.19 (θ₂=about 45), about 0.19 (θ₂=about 60), about 0.27 (θ₂=about 70), and about 0.27 (θ₂=about 85), respectively, in the LED packages shown in FIGS. 12A to 12E.

On the table, the optimal result is about 0.62 obtained when the second angle θ₂ is about 30°, which is improved by about 226% in color mixing as compared to the related art (about 0.19).

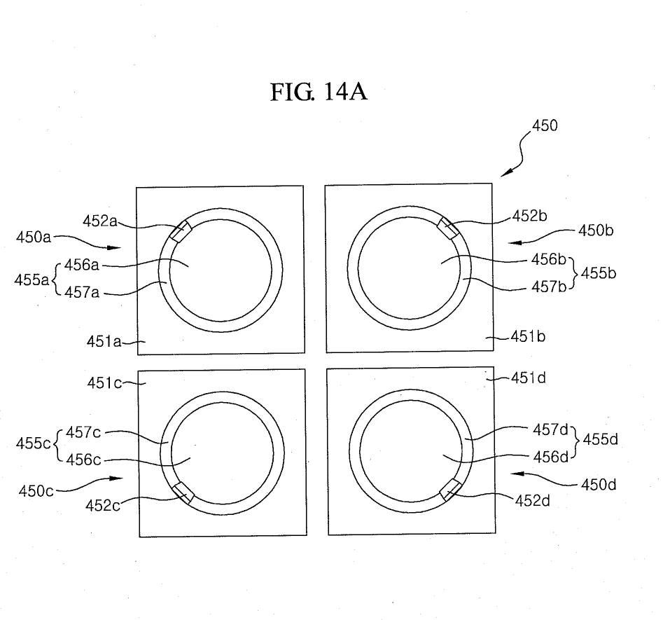

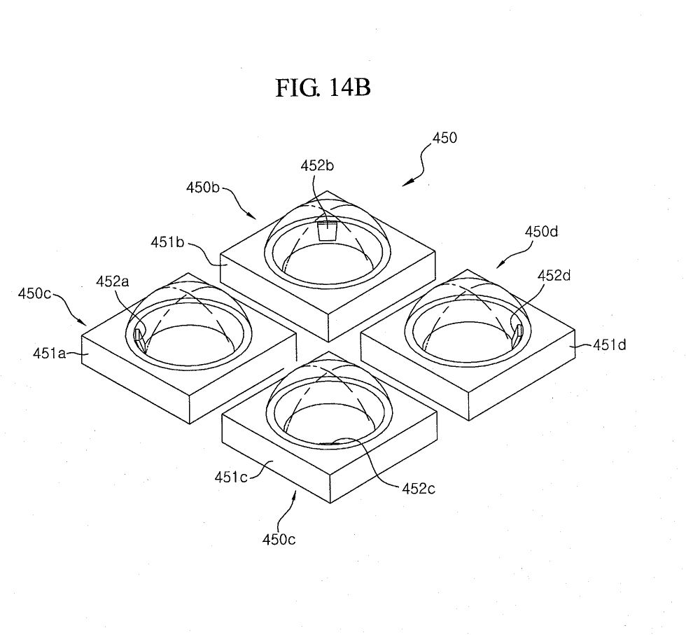

FIGS. 14A and 14B are a plan view and a perspective view of a LED package according to another embodiment of the present invention.

Referring to FIGS. 14A and 14B, a LED package unit 450 includes a plurality of LED packages (four LED packages in the present embodiment), that is, first to fourth LED packages (450a to 450d). As each LED package has the same constitution, only a first LED package 450a will be described hereafter. The first LED package 450a includes a substrate 451a, a first LED chip 452a, lead terminals, wires, a reflective part 455a, and a molding part 459. The reflective part 455a includes a base surface 456a that is parallel to the upper surface of the substrate 451a and formed to have a predetermined recessed depth, and a sidewall 457a that is inclined at a predetermined angle with respect to the base surface 456a.

A single LED chip 452a is mounted on the sidewall 457a at a predetermined angle with respect to the base surface 456a. In the meantime, the first to fourth LED chips in the LED package unit 450 may be disposed at a regular interval.

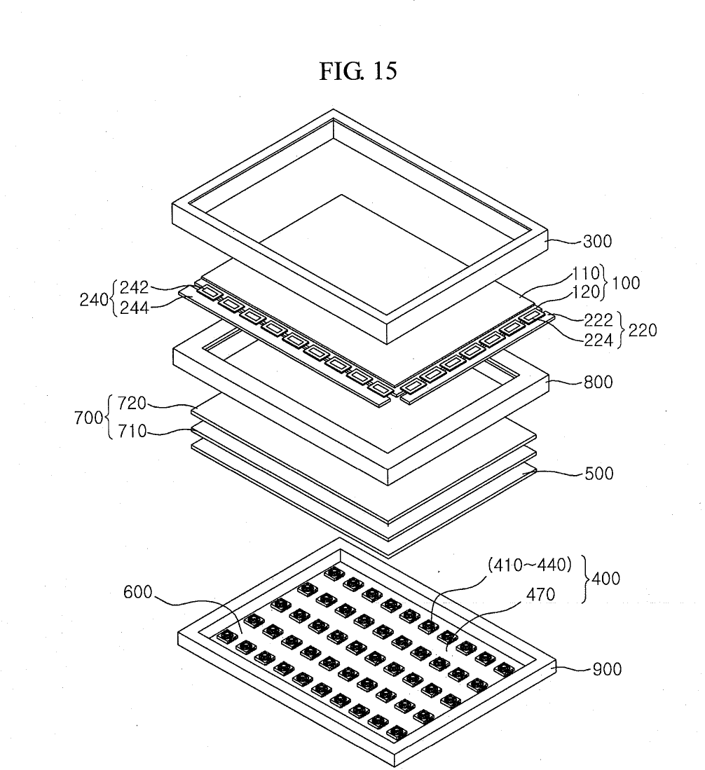

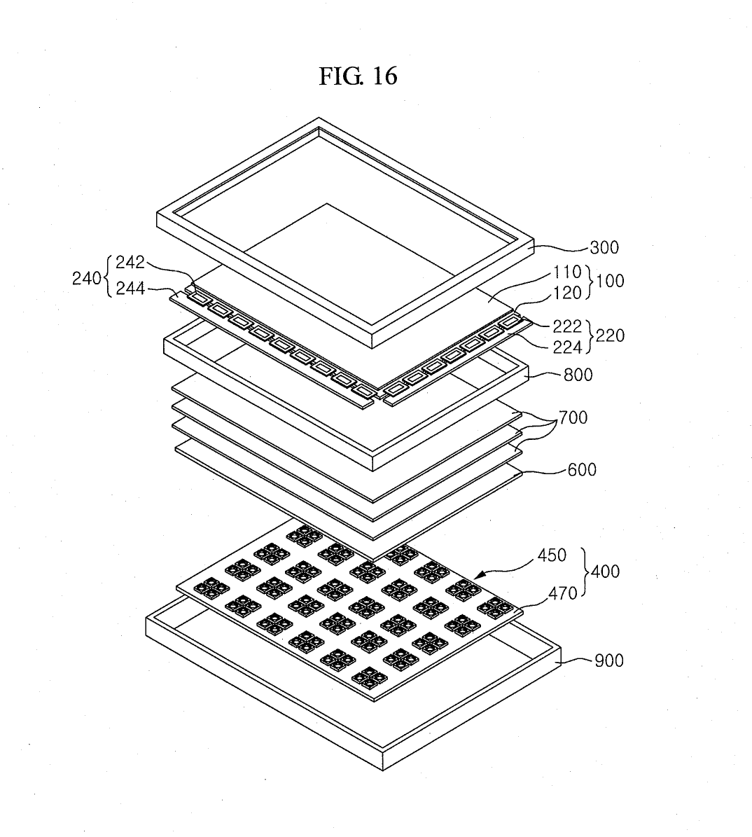

FIGS. 15 and 16 are exploded perspective views of one and another examples of a liquid crystal display that is provided with a backlight including the LED packages according to the present invention.

Referring to FIGS. 15 and 16, a liquid crystal display includes an upper receiving member 300, a liquid crystal display panel 100, driving circuit parts 220 and 240, a diffusion plate 600, a plurality of optical sheets 700, a light source unit 400, a mold frame 800, and a lower receiving member 900.

A predetermined receiving space is formed in the mold frame 800. A backlight unit, which includes the diffusion plate 600, the plurality of optical sheets 700, and the light source unit 400, is disposed in the receiving space of the mold frame. The liquid crystal display panel 100 for displaying image is disposed on the upper side of the backlight unit.

The driving circuit parts 220 and 240 are connected to the liquid crystal display panel 100. The driving circuit parts 220 and 240 include a gate printed circuit board 224, a data printed circuit board 244, a gate flexible printed circuit board 222, and a data flexible printed circuit board 242. The gate printed circuit board 224 is connected to the liquid crystal display panel 100, and a control IC is mounted on the gate printed circuit board 224. Further, the gate printed circuit board 224 applies a predetermined gate signal to a gate line of a thin film transistor (TFT) substrate 120. The data printed circuit board 244 is connected to the liquid crystal display panel 100, and a control IC is mounted on the data printed circuit board 244. Further, the data printed circuit board 244 applies a predetermined data signal to a data line of a TFT substrate 120. The gate flexible printed circuit board 222 connects the TFT substrate 120 to the gate printed circuit board 224, and the data flexible printed circuit board 242 connects the TFT substrate 120 to the data printed circuit board 244. The gate and data printed circuit boards 224 and 244 are connected to the gate and data flexible printed circuit boards 222 and 242 to apply a gate driving signal and an external image signal to the gate and data flexible printed circuit boards. At this time, the gate and data printed circuit boards 224 and 244 may be integrated into one printed circuit board. In addition, the flexible printed circuit boards 222 and 242 have a driving IC mounted therein, to transmit power and RGB (Red, Green, and Blue) signals generated from the printed circuit boards 224 and 244 to the liquid crystal display panel 100.

The light source unit 400 includes the above-described LED packages 410 to 440 and a printed circuit board 470 having the LED packages 410 to 440 mounted thereon (see FIG. 15).

In the meantime, the light source unit 400 shown in FIG. 16 includes the LED package unit 450 shown in FIGS. 14A and 14B and the printed circuit board 470 having the LED package unit 450 mounted thereon.

The diffusion plate 600 and the plurality of optical sheets 700 are disposed on the upper side of the light source unit 400 to uniformize luminance distribution of light emitted from the light source unit 400. The upper accommodation member 300 is joined with the mold frame 800 so as to cover edges of the liquid crystal display panel 100, that is, a non-display region and a side surface and a bottom surface of the mold frame 800. The lower accommodation member 900 is disposed at the lower side of the mold frame 800 to close the accommodating space of the mold frame.

As described above, according to exemplary embodiments of the present invention, as the LED chip is mounted on the sidewall of the reflective part formed on the substrate, it is possible to improve color mixing of light emitted by the LED package.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A LED package comprising:
a substrate in which an inner wall is formed in a recessed shape; and
at least one LED chip mounted on the inner wall of the substrate,
wherein the inner wall includes a base surface and a sidewall inclined at a first angle with respect to the base surface, and the LED chip is mounted on the sidewall.

2. The LED package of claim 1, wherein the base surface and the sidewall are integrally formed.

3. The LED package of claim 1, wherein the LED chip is composed of a plurality of LED chips, and the plurality of LED chips is mounted on the sidewall at an interval.

4. The LED package of claim 3, wherein the plurality of LED chips is mounted on the sidewall at an equal interval.

5. The LED package of claim 1, wherein the first angle is in the range from about 120 to about 150°.

6. The LED package of claim 1, wherein the inner wall comprises a reflective part.

7. The LED package of claim 6, further comprising:
a protrusion formed on the base surface.

8. The LED package of claim 7, wherein the protrusion is formed to have a height equal to or smaller than a depth of the reflective part.

9. The LED package of claim 7, wherein the protrusion includes a reflective surface that is inclined at a second angle with respect to the base surface.

10. The LED package of claim 9, wherein the second angle is in the range from about 5 to about 85°.

11. The LED package of claim 9, wherein the protrusion is formed in a shape comprising one of a conical shape or a polypyramidal shape.

12. The LED package of claim 1, wherein the LED chip includes at least one of a red LED chip, a green LED chip, and a blue LED chip.

13. The LED package of claim 1, wherein the LED chip includes a white LED chip.

14. The LED package of claim 1, further comprising:
lead terminals and wires used to apply power to the LED chip.

15. The LED package of claim 1, further comprising:
a molding part for sealing the LED chip.

16. The LED package of claim 1, wherein the base surface is formed in a shape comprising one of a circular shape, a polygonal shape, or a polygonal shape having curves.

17. The LED package of claim 16, wherein the sidewall comprises a flat surface.

18. A backlight unit comprising:
a LED package including a substrate in which a reflective part is formed in a recessed shape, and a plurality of LED chips mounted on the reflective part of the substrate, the reflective part including a base surface and a sidewall that is inclined at a first angle with respect to the base surface, and the plurality of LED chips being mounted on the sidewall; and
a printed circuit board on which the LED package is mounted.

19. The backlight unit of claim 18, further comprising:
a protrusion including a reflective surface that is inclined at a second angle with respect to the base surface.

20. A backlight unit comprising:
a LED package including a substrate in which a reflective part is formed in a recessed shape, and a single LED chip mounted on the reflective part of the substrate, the reflective part including a base surface and a sidewall that is inclined at a first angle with respect to the base surface, the single LED chip being mounted on the sidewall; and
a printed circuit board on which a plurality of the LED packages is mounted,
wherein the plurality of light emitting diodes is divided into light emitting diode units, wherein each light emitting diode unit includes a plurality of light emitting diodes, so as to be mounted on the printed circuit board.

21. The backlight unit of claim 20, further comprising:
a protrusion including a reflective surface that is inclined at a second angle with respect to the base surface.

22. A liquid crystal display comprising:
a backlight unit including,
a LED package that includes a substrate in which a reflective part is formed in a recessed shape and a plurality of LED chips mounted on the reflective part of the substrate, in which the reflective part includes a base surface and a sidewall inclined at a first angle with respect to the base surface and the plurality of LED chips are mounted on the sidewall, and
a printed circuit board on which the plurality of LED packages are mounted; and
a liquid crystal display panel disposed on the backlight unit to display an image.

23. The liquid crystal display of claim 22, further comprising:
a protrusion including a reflective surface that is inclined at a second angle with respect to the base surface.

24. A liquid crystal display comprising:
a backlight unit including,
a LED package including a substrate in which a reflective part is formed in a recessed shape, and a single LED chip mounted on the reflective part of the substrate, the reflective part including a base surface and a sidewall inclined at a first angle with respect to the base surface, the single LED chip being mounted on the sidewall, and
a printed circuit board on which the plurality of LED packages are mounted, the plurality of LED packages being divided into LED package units that each include a plurality of LED packages so as to be mounted on the printed circuit board; and
a liquid crystal display panel disposed on the backlight unit to display an image.

25. The liquid crystal display of claim 24, further comprising:
a protrusion including a reflective surface that is inclined at a second angle with respect to the base surface.
